(19) United States
(12) Patent Application Publication
(10) Pub. No.: US 2025/0153302 A1
(43) Pub. Date: May 15, 2025

(54) INFORMATION PROCESSING APPARATUS, INFERENCE APPARATUS, MACHINE-LEARNING APPARATUS, INFORMATION PROCESSING METHOD, INFERENCE METHOD, AND MACHINE-LEARNING METHOD

(71) Applicant: EBARA CORPORATION, Tokyo (JP)

(72) Inventor: Seungho YUN, Tokyo (JP)

(73) Assignee: EBARA CORPORATION, Tokyo (JP)

(21) Appl. No.: 18/833,522

(22) PCT Filed: Jan. 25, 2023
(86) PCT No.: PCT/JP2023/002243

§ 371 Date: Jul. 26, 2024

(30) Foreign Application Priority Data
Feb. 9, 2022 (JP) 2022-018782
Dec. 15, 2022 (JP) 2022-200006

(51) Int. Cl. B24B 37/005

(52) U.S. Cl. CPC B24B 37/0053

(57) ABSTRACT

An information processing apparatus (5) includes: an information acquisition section (500) configured to acquire polishing condition information including top-ring vibration information indicating vibration of a top ring in chemical mechanical polishing of the substrate and top-ring sound information indicating sound generated from the top ring in the chemical mechanical polishing of the substrate performed by a substrate processing apparatus including a polishing table rotatably supporting the polishing pad and the top ring configured to press the substrate against the polishing pad; and a state prediction section (501) configured to predict substrate slip-out information for the polishing condition information by inputting the polishing condition information acquired by the information acquisition section (500) to a learning model (10A) that has been generated by machine learning that causes the learning model to learn a correlation between the polishing condition information and the substrate slip-out information indicating occurrence of slip out of the substrate on which the chemical mechanical polishing is performed.

### TECHNICAL FIELD

The present invention relates to an information processing apparatus, an inference apparatus, a machine-learning apparatus, an information processing method, an inference method, and a machine-learning method.

### BACKGROUND ART

A substrate processing apparatus that performs chemical mechanical polishing (CMP) is known as a type of substrate processing apparatuses that performs various processing on a substrate, such as a semiconductor wafer. In the chemical-mechanical-polishing process, for example, a substrate is chemically and mechanically polished by pressing the substrate against a polishing pad by a polishing head, which is referred to as a top ring, with a polishing liquid (e.g., slurry) being supplied onto the polishing pad from a polishing-fluid supply nozzle, while a polishing table having the polishing pad is being rotated. When the substrate is being polished, a slip-out problem in which the substrate comes out from the top ring may occur (for example, see Patent document 1).

### CITATION LIST

### Patent Literature

Patent document 1: Japanese laid-open patent publication No. 2005-259979

### SUMMARY OF INVENTION

### Technical Problem

It is effective in controlling the production quality and the yield of the substrate if a state of the substrate, such as the stress applied to the substrate by chemical mechanical polishing, during or after processing can be appropriately monitored, or if the state of the substrate can be predicted at an arbitrary timing before, during, or after processing. However, it is not realistic to directly attach some kind of sensor to each substrate in order to detect the state of the substrate. In addition, when the chemical mechanical polishing of the substrate is performed by the substrate processing apparatus, the state of the substrate fluctuates according to operating states of the top ring and the polishing table of the substrate processing apparatus. These operating states act complexly and mutually on the substrate. Therefore, it is difficult to accurately analyze the effects of the respective operating states on the slip out of the substrate.

In view of the above-mentioned drawbacks, it is an object of the present invention to provide an information processing apparatus, an inference apparatus, a machine-learning apparatus, an information processing method, an inference method, and a machine-learning method capable of appropriately predicting a substrate lip-out information indicating an occurrence of a slip out of a substrate a during or after chemical mechanical polishing.

### Solution to Problem

In order to achieve the above object, an information processing apparatus according to one embodiment of the present invention includes:

an information acquisition section configured to acquire polishing condition information including top-ring vibration information indicating vibration of a top ring in chemical mechanical polishing of the substrate and top-ring sound information indicating sound generated from the top ring in the chemical mechanical polishing of the substrate performed by a substrate processing apparatus including a polishing table rotatably supporting the polishing pad and the top ring configured to press the substrate against the polishing pad; and a state prediction section configured to predict substrate slip-out information for the polishing condition information by inputting the polishing condition information acquired by the information acquisition section to a learning model that has been generated by machine learning that causes the learning model to learn a correlation between the polishing condition information and the substrate slip-out information indicating occurrence of slip out of the substrate on which the chemical mechanical polishing is performed.

### Advantageous Effects of Invention

According to the information processing apparatus of the embodiment of the present invention, the polishing condition information including the top-ring state information and the polishing-table state information in the chemical mechanical polishing are input to the learning model, so that the substrate slip-out information for the polishing condition information can be predicted. Therefore, the substrate slip-out information during or after the chemical mechanical polishing can be predicted appropriately.

Objects, configurations, and effects other than those described above will be made clear in detailed descriptions of the invention described below.

### BRIEF DESCRIPTION OF DRAWINGS

FIG. 1 is an overall configuration diagram showing an example of a substrate processing system 1;

FIG. 2 is a plan view showing an example of a substrate processing device 2;

FIG. 3 is a perspective view showing an example of first to fourth polishing sections 22A to 22D;

FIG. 4 is a cross-sectional view schematically showing an example of a top ring 221;

FIG. 5 is a block diagram showing an example of the substrate processing device 2;

FIG. 6 is a hardware configuration diagram showing an example of a computer 900;

FIG. 7 is a data configuration diagram showing an example of production history information 30 managed by a database device 3;

FIG. 8 is a data configuration diagram showing an example of polishing-test information 31 managed by the database device 3;

FIG. 9 is a block diagram showing an example of a machine-learning device 4 according to a first embodiment;

FIG. 10 is a diagram showing an example of a first learning model 10A and first learning data 11A;

FIG. 11 is a flowchart illustrating an example of a machine-learning method performed by the machine-learning device 4;

FIG. 12 is a block diagram showing an example of an information processing device 5 according to the first embodiment;

FIG. 13 is a functional explanatory diagram showing an example of the information processing device 5 according to the first embodiment;

FIG. 14 is a flowchart illustrating an example of an information processing method performed by the information processing device 5;

FIG. 15 is a block diagram showing an example of a machine-learning device 4a according to a second embodiment;

FIG. 16 is a diagram showing an example of a second learning model 10B and second learning data 11B;

FIG. 17 is a block diagram showing an example of an information processing device 5a functioning as the information processing device 5a according to the second embodiment; and

FIG. 18 is a functional explanatory diagram showing an example of the information processing device 5a according to the second embodiment.

### DESCRIPTION OF EMBODIMENTS

Embodiments for practicing the present invention will be described below with reference to the drawings. In the following descriptions, scope necessary for the descriptions to achieve the object of the present invention will be schematically shown, scope necessary for the descriptions of relevant parts of the present invention will be mainly described, and parts omitted from the descriptions will be based on known technology.

### First Embodiment

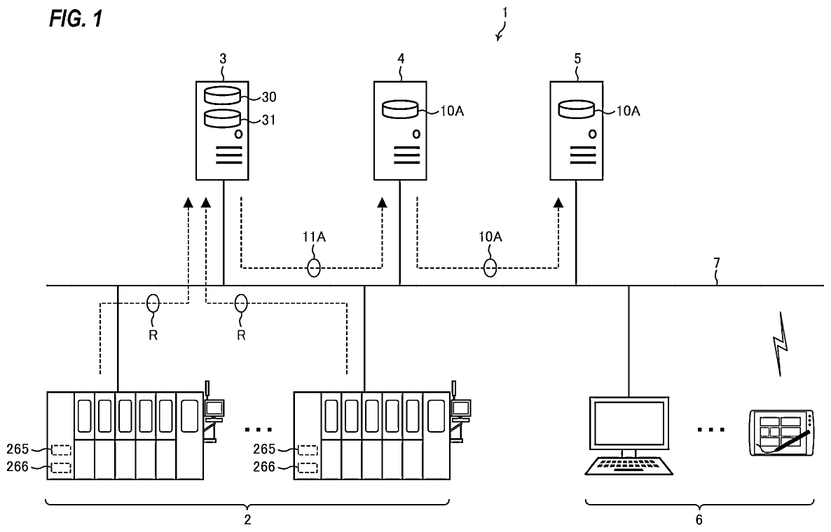

FIG. 1 is an overall configuration diagram showing an example of a substrate processing system 1. The substrate processing system 1 according to this embodiment functions as a system configured to manage a series of substrate processes including a chemical mechanical polishing (hereinafter referred to as “polishing process”) of planarizing a surface of a substrate (hereinafter referred to as a “wafer”) W, such as a semiconductor wafer, and a cleaning process of cleaning the wafer W after polishing. In embodiments of this specification, examples of the semiconductor wafer are not limited to a circular wafer, and may include a CCL substrate (Copper Clad Laminate substrate), a PCB (Printed Circuit Board) substrate, a photomask substrate, and a quadrilateral substrate, such as display panel.

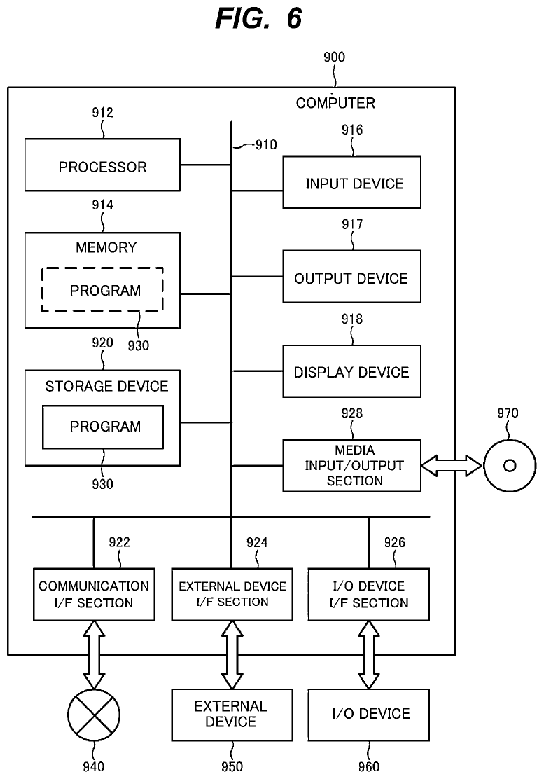

The substrate processing system 1 includes, as its main components, substrate processing devices 2, a database device 3, a machine-learning device 4, an information processing device 5, and a user terminal device 6. Each of the devices 2 to 6 is configured with, for example, a general-purpose computer or dedicated computer (see FIG. 6 described later). The devices 2 to 6 are coupled to a wired or wireless network 7 so as to be able to transmit and receive various data (some data are shown in FIG. 1 with dotted arrows). The number of devices 2 to 6 and the connection configuration of the network 7 are not limited to the example shown in FIG. 1, and may be changed as appropriate.

Each substrate processing device 2 is composed of units and is configured to perform a series of substrate processes on one or more wafers W, such as loading, polishing, cleaning, drying, film-thickness measuring, and unloading. During the processes, the substrate processing device 2 controls operations of the units while referring to device setting information 265 including device parameters that have been set for the units and substrate recipe information 266 that determines polishing condition information of the polishing process, cleaning conditions of the cleaning process, etc.

The substrate processing device 2 is configured to transmit various reports R to the database device 3, the user terminal device 6, etc. according to the operation of each unit. The various reports R include, for example, process information that identifies a wafer W on which substrate processing is performed, device-state information that indicates a state of each unit when each process is performed, event information detected by the substrate processing device 2, and manipulation information of a user (an operator, a production manager, a maintenance manager, etc.) on the substrate processing device 2.

The database device 3 is an apparatus that manages production history information 30 on a history when substrate processing is performed on a wafer W for proper production, and polishing-test information 31 on a history when a test of polishing (hereinafter referred to as “polishing test”) is performed on a dummy wafer for testing. In addition to the above information, the database device 3 may also store the device setting information 265 and the substrate recipe information 266. In that case, the substrate processing device 2 may refer to these information.

The database device 3 receives various reports R from the substrate processing device 2 when the substrate processing device 2 has performed substrate processing on the wafer W for proper production, and registers the various reports R in the production history information 30, so that the reports R on the substrate processing are accumulated in the production history information 30.

When the substrate processing device 2 performs the polishing test on the dummy wafer for testing, the database device 3 receives the various reports R (including at least the device-state information) from the substrate processing device 2, registers the reports R in the polishing-test information 31, and registers test results of the polishing test associated with the various reports R, so that the reports R and the test results on the polishing test are accumulated in the polishing-test information 31. The dummy wafer is a tool imitating the wafer W. Dummy-wafer sensors, such as a pressure sensor and a temperature sensor, are disposed on a surface of the dummy wafer or in the dummy wafer, and are each configured to measure a state of the wafer W when the polishing process is performed on the wafer W. Measurement values of the dummy-wafer sensors are registered as the test results in the polishing-test information 31. The dummy-wafer sensor(s) may be disposed at one or a plurality of portions of a substrate surface of the dummy wafer, or may be disposed in a planar arrangement. The polishing test may be performed by the substrate processing device 2 for proper production, or may be performed by a polishing-test device (not shown) for testing capable of performing the same polishing process as that of the substrate processing device 2.

The machine-learning device 4 operates as a main configuration for a learning phase in machine learning. For example, the machine-learning device 4 acquires, as first learning data 11A, part of the polishing-test information 31 from the database device 3, and performs the machine learning to create a first learning model 10A to be used in the information processing device 5. The first learning model 10A as a learned model is provided to the information processing device 5 via the network 7, a storage medium, or the like.

The information processing device 5 operates as a main configuration for an inference phase in the machine learning. When the polishing process is performed on the wafer W for proper production by the substrate processing device 2, the information processing device 5 predicts a state of the wafer W using the first learning model 10A created by the machine-learning device 4, and transmits substrate slip-out information, which is a result of the prediction, to the database device 3, the user terminal device 6, etc. The timing at which the information processing device 5 predicts the substrate slip-out information may be after the polishing process (i.e., post-predicting process), during the polishing process (i.e., real-time-predicting process), or before the polishing process (i.e., pre-predicting process).

The user terminal device 6 is a terminal device used by a user. The user terminal device 6 may be a stationary device or a portable device. The user terminal device 6 receives various input manipulations via a display screen of an application program, a web browser, etc., and displays various information (e.g., a notification of event, the substrate slip-out information, the production history information 30, the polishing-test information 31, etc.) via the display screen.

(Substrate processing device 2)

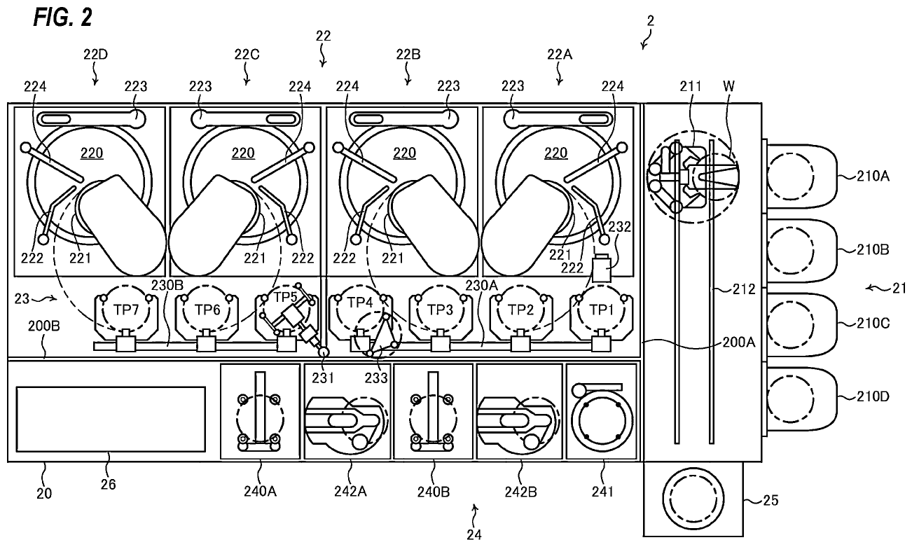

FIG. 2 is a plan view showing an example of the substrate processing device 2. The substrate processing device 2 includes a load-unload unit 21, a polishing unit 22, a substrate transport unit 23, a cleaning unit 24, a film-thickness measuring unit 25, and a control unit 26 which are arranged inside a housing 20 that is substantially rectangular in a plan view. The load-unload unit 21 is isolated from the polishing unit 22, the substrate transport unit 23, and the cleaning unit 24 by a first partition wall 200A. The substrate transport unit 23 is isolated from the cleaning unit 24 by a second partition wall 200B.

(Load-unload unit)

The load-unload unit 21 includes first to fourth front load sections 210A to 210D on which wafer cassettes (FOUPs, etc.), each capable of storing a large number of wafers W along a vertical direction, are placed, a transfer robot 211 that is movable along the storage direction (vertical direction) of the wafers W in each wafer cassette, and a horizontally-moving mechanism 212 for moving the transfer robot 211 along an arrangement direction of the first to fourth front load sections 210A to 210D (i.e., along a direction of a shorter side of the housing 20).

The transfer robot 211 is configured to be accessible to the wafer cassette placed on each of the first to fourth front load sections 210A to 210D, the substrate transport unit 23 (specifically, a lifter 232, which will be described later), the cleaning unit 24 (specifically, a drying chamber 241, which will be described later), and the film-thickness measuring unit 25. The transfer robot 211 includes upper and lower hands (not shown) for transporting the wafer W between the wafer cassette, the substrate transport unit 23, the cleaning unit 24, and the film-thickness measuring unit 25. The lower hand is used when transporting the wafer W before processing of the wafer W, and the upper hand is used when transporting the wafer W after processing of the wafer W. When the wafer W is transported to and from the substrate transport unit 23 or the cleaning unit 24, a shutter (not shown) provided on the first partition wall 200A is opened and closed.

(Polishing unit)

The polishing unit 22 includes first to fourth polishing sections 22A to 22D each configured to perform the polishing process (planarization) on the wafer W. The first to fourth polishing sections 22A to 22D are arranged in parallel along the longitudinal direction of the housing 20.

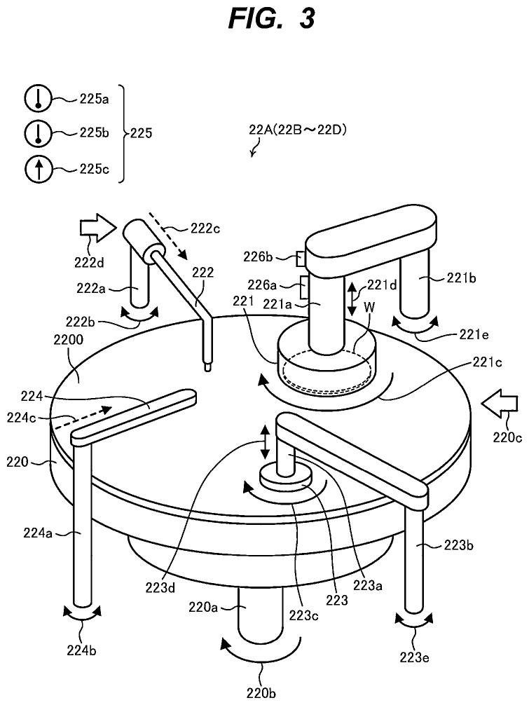

FIG. 3 is a perspective view showing an example of the first to fourth polishing sections 22A to 22D. The first to fourth polishing sections 22A to 22D have common basic configurations and functions.

Each of the first to fourth polishing sections 22A to 22D includes a polishing table 220 to which a polishing pad 2200 having a polishing surface is attached, a top ring (polishing head) 221 configured to hold the wafer W and to polish the wafer W while pressing the wafer W against the polishing pad 2200 on the polishing table 220, a polishing-fluid supply nozzle 222 configured to supply a polishing fluid onto the polishing pad 2200, a dresser 223 configured to dress the polishing surface of the polishing pad 2200, an atomizer 224 configured to emit a cleaning fluid to the polishing pad 2200, and an environment sensor 225 configured to measure a state of an internal space of the housing 20 where the polishing process is performed.

The polishing table 220 is supported by a polishing table shaft 220a. The polishing table 220 includes a rotating mechanism 220b configured to rotate the polishing table 220 about its own axis, and a temperature regulating mechanism 220c configured to regulate a surface temperature of the polishing pad 2200.

The top ring 221 is supported by a top-ring shaft 221a that is movable in the vertical direction. The top ring 221 includes a rotating mechanism 221c configured to rotate the top ring 221 about an axis of the top ring 221, a vertical movement mechanism 221d configured to move the top ring 221 in the vertical direction, and an oscillation mechanism 221e configured to rotate (or oscillate) the top ring 221 around a support shaft 221b as a pivot center.

The polishing-fluid supply nozzle 222 is supported by a support shaft 222a. The polishing-fluid supply nozzle 222 includes an oscillation mechanism 222b configured to rotate and move the polishing-fluid supply nozzle 222 around the support shaft 222a as a pivot center, a flow-rate regulator 222c configured to regulate a flow rate of the polishing fluid, and a temperature regulating mechanism 222d configured to regulate a temperature of the polishing fluid. The polishing fluid is a polishing liquid (e.g., slurry) or pure water, which may further include a chemical liquid, or may be a polishing liquid to which a dispersant is added.

The dresser 223 is supported by a dresser shaft 223a that is movable in the vertical direction. The dresser 223 includes a rotating mechanism 223c configured to rotate about its own axis, a vertical movement mechanism 223d configured to move the dresser 223 in the vertical direction, and an oscillation mechanism 223e configured to rotate and move the dresser 223 around a support shaft 223b as a pivot center.

The atomizer 224 is supported by a support shaft 224a. The atomizer 224 includes an oscillation mechanism 224b configured to rotate and move the atomizer 224 around the support shaft 224a as a pivot center, and a flow-rate regulator 224c configured to regulate a flow rate of the cleaning fluid. The cleaning fluid is a mixture of liquid (e.g., pure water) and gas (e.g., nitrogen gas), or liquid (e.g., pure water).

The environment sensor 225 is constituted of sensors arranged in the internal space of the housing 20. The environment sensor 225 includes, for example, a temperature sensor 225a configured to measure temperature of the internal space, a humidity sensor 225b configured to measure humidity of the internal space, and an atmospheric-pressure sensor 225c configured to measure atmospheric pressure of the internal space. The environment sensor 225 may include a camera (image sensor) configured to be able to generate an image of a surface of the polishing pad 2200 or the like during, before, or after the polishing process.

A top-ring vibration sensor 226a is mounted to the top ring 221. The top-ring vibration sensor 226a may be at least one of an acceleration sensor configured to detect an acceleration of vibration, a speed sensor configured to detect a speed of vibration, and a displacement sensor configured to detect a displacement of vibration. The top-ring vibration sensor 226a may be mounted to any part of the top ring 221, such as the top ring shaft 221a.

Furthermore, a top-ring sound sensor 226b is mounted to the top ring 221. The top-ring sound sensor 226b may be at least one of a directional microphone configured to detect an operating sound of the top ring 221, and a directional microphone configured to detect a processing sound emitted from the polishing surface by the top ring 221. The top-ring sound sensor 226b may be mounted to any part of the top ring 221, such as the top ring shaft 221a. In a case where the top-ring sound sensor 226b is the directional microphone, the top-ring sound sensor 226b may be installed anywhere other than the top ring 221.

In FIG. 3, specific configurations of the rotating mechanisms 220b, 221c, 223c, the vertical movement mechanisms 221d, 223d, and the oscillation mechanisms 221e, 222b, 223e, 224b are omitted, but each mechanism may be constructed by appropriately combining module for generating driving force (e.g., motor, actuator), driving force transmission mechanism (e.g., linear guide, ball screw, gear, belt, coupling, bearing, and sensor (e.g., linear sensor, encoder sensor, limit sensor, torque sensor). In FIG. 3, specific configurations of the flow-rate regulator 222c and 224c are omitted, but the flow-rate regulator 222c and 224c may be constructed by appropriately combining module for regulating a flow rate (e.g., pump, valve, a regulator), and sensor (e.g., flow-rate sensor, pressure sensor, liquid-level sensor). In FIG. 3, specific configurations of the temperature regulating mechanisms 220c and 222d are omitted, but the temperature regulating mechanisms 220c and 222d may be constructed by appropriately combining modules (conduction type, radiation type, convection type) for regulating temperature (e.g., heater, heat exchanger), and sensor, (e.g., temperature sensor, current sensor).

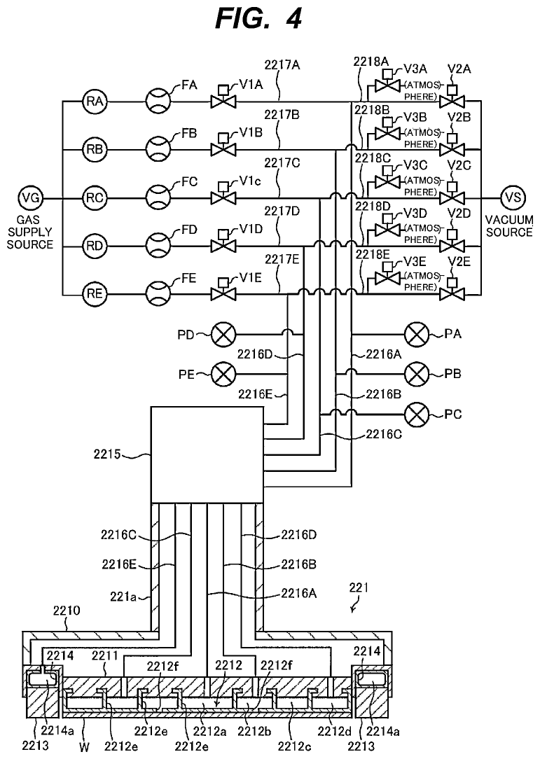

FIG. 4 is a cross-sectional view schematically showing an example of the top ring 221. The top ring 221 includes a top ring body 2210 attached to the top ring shaft 221a, a substantially disc-shaped carrier 2211 arranged in the top ring body 2210, a membrane 2212 arranged beneath the carrier 2211 and configured to press the wafer W against the polishing pad 2200, a substantially annular retainer ring 2213 that is disposed at peripheries of the carrier 2211 and the membrane 2212 and configured to directly press the polishing pad 2200, and a retainer-ring airbag 2214 as a retainer-ring pressing mechanism arranged between the top ring body 2210 and the retainer ring 2213 and configured to press the retainer ring 2213 against the polishing pad 2200.

In this embodiment, the retaining-ring airbag 2214 is used as the retainer-ring pressing mechanism, while the retainer-ring pressing mechanism may be a fluid actuator using air, water, oil, etc., or an electric actuator using a ball screw, etc., or an elastic member including a spring or a bag.

The membrane 2212 is an elastic membrane, and has a plurality of concentric partition walls 2212e therein that form four membrane pressure chambers 2212a to 2212d arranged concentrically from the center toward the circumference of the top ring body 2210. Further, the membrane 2212 has a plurality of holes 2212f for attracting the wafer W to a lower surface of the membrane 2212, and functions as a substrate holding surface for holding the wafer W. The retainer-ring airbag 2214 is formed of an elastic membrane and has a retaining-ring pressure chamber 2214a therein. The configurations of the top ring 221 may be changed as appropriate, and the top ring 221 may have a pressure chamber that presses the entire carrier 2211. The number and shape of the membrane pressure chambers of the membrane 2212 may be changed as appropriate. The number and arrangement of the suction holes 2212f may be changed as appropriate. Furthermore, the membrane 2212 may not have the suction holes 2212f.

First to fourth flow paths 2216A to 2216D are coupled to the first to fourth membrane pressure chambers 2212a to 2212d, respectively, and a fifth flow path 2216E is coupled to the retaining-ring pressure chamber 2214a. The first to fifth flow paths 2216A to 2216E communicate with an exterior via a rotary joint 2215 provided on the top ring shaft 221a. The first to fifth flow paths 2216A to 2216E are divided into first branch paths 2217A to 2217E and second branch paths 2218A to 2218E. Pressure sensors PA to PE are installed in the first to fifth flow paths 2216A to 2216E, respectively. The first branch paths 2217A to 2217E are coupled to a gas supply source GS of pressurized fluid (air, nitrogen, etc.) via valves V1A to V1E, flow-rate sensors FA to FE, and pressure regulators RA to RE. The second branch paths 2218A to 2218E are coupled to a vacuum source VS via valves V2A to V2E, respectively, and are configured to be able to communicate with the atmosphere via valves V3A to V3E.

The wafer W is attracted and held on the lower surface of the top ring 221 and is moved to a predetermined polishing position above the polishing table 220. Thereafter, the wafer W is polished by being pressed by the top ring 221 against the polishing surface of the polishing pad 2200 on which the polishing fluid is suppled from the polishing-fluid supply nozzle 222. At this time, the top ring 221 controls the pressure regulators RA to RE independently to generate pressing forces that press the wafer W against the polishing pad 2200 via the pressurized fluid supplied to the first to fourth membrane pressure chambers 2212a to 2212d while adjusting the pressing forces for respective regions of the wafer W. A pressing force for pressing the retainer ring 2213 against the polishing pad 2200 is adjusted by the pressurized fluid supplied to the retainer-ring pressure chamber 2214a. The pressures of the pressurized fluid supplied to the first to fourth membrane pressure chambers 2212a to 2212d and the retaining-ring pressure chamber 2214a are measured by the pressure sensors PA to PE, respectively, and the flow rates of the pressurized gas are measured by the flow-rate sensors FA to FE, respectively.

### Substrate Transport Unit)

As shown in FIG. 2, the substrate transport unit 23 includes first and second linear transporters that are horizontally movable along the arrangement direction of the first to fourth polishing sections 22A to 22D (i.e., the longitudinal direction of the housing 20), a swing transporter 231 arranged between the first and second linear transporters 230A, 230B, a lifter 232 arranged near the load-unload unit 21, and a temporary station 233 for the wafer W arranged near the cleaning unit 24.

The first linear transporter 230A is arranged adjacent to the first and second polishing sections 22A and 22B and is configured to transport the wafer W to four transfer positions (which will be referred to as first to fourth transfer positions TP1 to TP4 in the order from the load-unload-unit-21-side). The second transfer position TP2 is a position where the wafer W is delivered to the first polishing section 22A, and the third transfer position TP3 is a position where the wafer W is delivered to the second polishing section 22B.

The second linear transporter 230B is arranged adjacent to the third and fourth polishing sections 22C and 22D and is configured to transport the wafer W to three transfer positions (which will be referred to as fifth to seventh transfer positions TP5 and TP7 in the order from the load-unload-unit-21-side). The sixth transfer position TP6 is a position where the wafer W is delivered to the third polishing section 22C, and the seventh transfer position TP7 is a position where the wafer W is delivered to the fourth polishing section 22D.

The swing transporter 231 is disposed adjacent to the fourth and fifth transfer positions TP4 and TP5. The swing transporter 231 has a hand that is movable between the fourth and fifth transfer positions TP4 and TP5. The swing transporter 231 is configured to transport the wafer W between the first and second linear transporters 230A and 230B and place the wafer W temporarily on the temporary station 233. The lifter 232 is disposed adjacent to the first transfer position TP1. The lifter 232 is configured to transport the wafer W between the first transfer position TP1 and the transfer robot 211 of the load-unload unit 21. When the wafer W is transported, the shutter (not shown) provided on the first partition wall 200A is opened and closed.

### (Cleaning Unit)

As shown in FIG. 2, the cleaning unit 24 includes first and second cleaning chambers 240A and 240B each configured to clean the wafer W using a cleaning tool, a drying chamber 241 configured to dry the wafer W, and first and second transfer chambers 242A and 242B each configured to transport the wafer W. The chambers of the cleaning unit 24 are isolated from each other, and are arranged along the first and second linear transporters 230A and 230B, for example, in an order of the first cleaning chamber 240A, the first transfer chamber 242A, the second cleaning chamber 240B, the second transfer chamber 242B, and the drying chamber 241 (in an order of distance from the load-unload unit 21). The number and arrangements of the cleaning chambers 240A and 240B, the drying chamber 241, and the transfer chambers 242A and 242B are not limited to the example in FIG. 2, and may be changed as appropriate.

### (Film-Thickness Measuring Unit)

The film-thickness measuring unit 25 is a measuring device that measures the film thickness of the wafer W before or after the polishing process. The film-thickness measuring unit 25 is, for example, an optical film-thickness measuring device, an eddy current type film-thickness measuring device, or the like. The transfer robot 211 transports the wafer W to and from each film-thickness measuring module.

### (Control Unit)

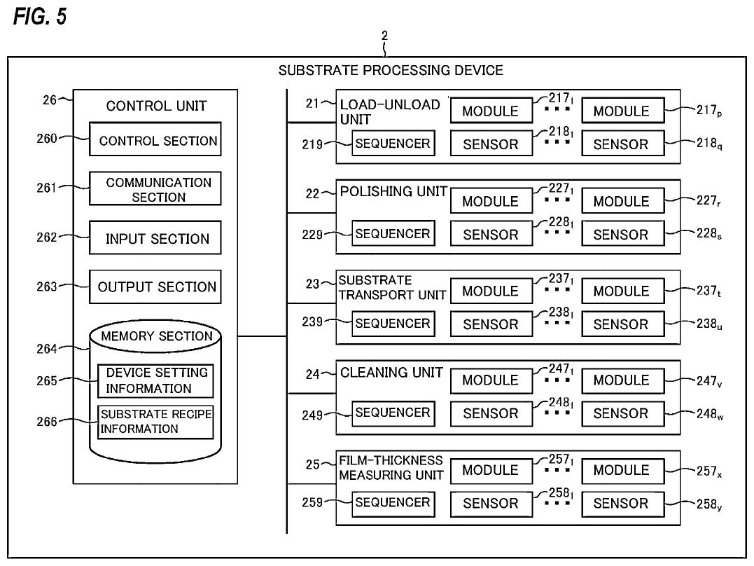

FIG. 5 is a block diagram showing an example of the substrate processing device 2. The control unit 26 is electrically coupled to each of the units 21 to 25, and functions as a control section that comprehensively controls the units 21 to 25. In this embodiment, a control system (i.e., modules, sensors, and a sequencer) of the polishing unit 22 will be described as an example. Control systems of the other units 21, and 23 to 25 have common basic configurations and functions, and descriptions will be omitted.

The polishing unit 22 includes modules 2271 to 227r to be controlled, which are disposed in sub-units (e.g., the polishing table 220, the top ring 221, the polishing-fluid supply nozzle 222, the dresser 223, the atomizer 224) of the polishing unit 22, respectively, sensors 2281 to 228s arranged in modules 2271 to 227r, respectively, for detecting data (i.e., detection values) necessary for controlling the modules 2271 to 227r, and a sequencer 229 for controlling the operations of the modules 2271 to 227r based on the detection values obtained by the sensors 2281 to 228s.

Examples of the sensors 2281 to 228s of the polishing unit 22 may include a sensor configured to detect an acceleration of vibration of the top ring 221, a sensor configured to detect a speed of vibration of the top ring 221, a sensor configured to detect a displacement of vibration of the top ring 221, a sensor configured to detect an operating sound of the ring 221, a sensor configured to detect a processing sound of the polishing surface by the top ring 221, a sensor configured to detect a rotational torque of the top ring 221, a sensor configured to detect a driving current of the top ring 221, a sensor configured to detect a driving voltage of the top ring 221, sensors configured to detect pressures (positive pressure and negative pressure) in the first to fourth elastic membrane pressure chambers 2212a to 2212d and the retainer-ring pressure chamber 2214a, sensors configured to detect flow rates of the pressure fluid supplied to the chambers 2212a to 2212d and the retainer-ring pressure chamber 2214a, a sensor configured to detect a rotational torque of the polishing table 220, a sensor configured to detect a drive current of the polishing table 220, a sensor configured to detect a driving voltage of the polishing table 220, a sensor configured to detect a surface temperature of the polishing pad 2200, the environment sensor 225, etc.

The control unit 26 includes a control section 260, a communication section 261, an input section 262, an output section 263, and a memory section 264. The control unit 26 is comprised of, for example, a general-purpose or dedicated computer (see FIG. 6, which will be described later).

The communication section 261 is coupled to the network 7 and functions as a communication interface for transmitting and receiving various data. The input section 262 receives various input operations. The output section 263 functions as a user interface by outputting various information via a display screen, lighting of signal tower, or buzzer sound.

The memory section 264 stores therein various programs (operating system (OS), application programs, web browser, etc.) and data (the device setting information 265, the substrate recipe information 266, etc.) used in the operations of the substrate processing device 2. The device setting information 265 and the substrate recipe information 266 are data that can be edited by the user via the display screen.

The control section 260 obtains detection values of the multiple sensors 2181 to 218q, 2281 to 228s, 2381 to 238u, 2481 to 248w, 2581 to 258y (hereinafter referred to as “sensor group”) via multiple sequencers 219, 229, 239, 249, 259 (hereinafter referred to as “sequencer group”). The control section 260 operates the multiple modules 2171 to 217p, 2271 to 227r, 2371 to 237t, 2471 to 247v, and 2571 to 257x (hereinafter referred to as “module group”) in cooperation to perform a series of substrate processes including loading, polishing, cleaning, drying, film-thickness measuring, and unloading.

### (Hardware Configuration of Each Device)

FIG. 6 is a hardware configuration diagram showing an example of a computer 900. Each of the control unit 26, the database device 3, the machine-learning device 4, the information processing device 5, and the user terminal device 6 of the substrate processing device 2 is configured by the general-purpose or dedicated computer 900.

As shown in FIG. 6, main components of the computer 900 include buses 910, a processor 912, a memory 914, an input device 916, an output device 917, a display device 918, a storage device 920, a communication I/F (interface) section 922, an external device I/F section 924, an I/O (input/output) device I/F section 926, and a media input/output section 928. The above components may be omitted as appropriate depending on an application in which the computer 900 is used.

The processor 912 includes one or more arithmetic processing unit(s) (CPU (Central Processing Unit), MPU (Micro-processing unit), DSP (digital signal processor), GPU (Graphics Processing Unit), NPU (Neural Processing Unit), etc.), and operates as a controller configured to control the entire computer 900. The memory 914 stores various data and programs 930, and includes, for example, a volatile memory (DRAM, SRAM, etc.) that functions as a main memory, a non-volatile memory (ROM), a flash memory, etc.

The input device 916 includes, for example, a keyboard, a mouse, a numeric keypad, an electronic pen, etc., and functions as an input section. The output device 917 includes, for example, a sound (voice) output device, a vibration device, etc., and functions as an output section. The display device 918 includes, for example, a liquid crystal display, an organic EL display, electronic paper, a projector, etc., and functions as an output section. The input device 916 and the display device 918 may be configured integrally, such as a touch panel display. The storage device 920 includes, for example, HDD (Hard Disk Drive), SSD (Solid State Drive), etc., and functions as a storage section. The storage device 920 stores various data necessary for executing the operating system and the programs 930.

The communication I/F section 922 is coupled to a network 940, such as the Internet or an intranet (which may be the same as the network 7 in FIG. 1), in a wired manner or a wireless manner, and transmits and receives data to and from another computer according to a predetermined communication standard. The communication I/F section 922 functions as a communication unit that sends and receives information. The external device I/F section 924 is coupled to an external device 950, such as camera, printer, scanner, reader/writer, etc. in a wired manner or a wireless manner, and serves as a communication section that transmits and receives data to and from the external device 950 according to a predetermined communication standard. The I/O device I/F unit 926 is coupled to I/O devices 960, such as various sensors or actuators, and functions as a communication unit that transmits and receives various signals, such as detection signals from the sensors or control signals to the actuators, and data to and from the I/O devices 960. The media input/output unit 928 is constituted of a drive device, such as a DVD drive or a CD drive, and writes and reads data into and from medium (non-transitory storage medium) 970, such as a DVD or a CD.

In the computer 900 having the above configurations, the processor 912 calls the program 930 stored in the storage device 920 into the memory 914 and executes the program 930, and controls each part of the computer 900 via the buses 910. The program 930 may be stored in the memory 914 instead of the storage device 920. The program 930 may be stored in the medium 970 in an installable file format or an executable file format, and may be provided to the computer 900 via the media input/output unit 928. The program 930 may be provided to the computer 900 by being downloaded via the network 940 and the communication I/F unit 922. The computer 900 performs various functions realized by the processor 912 executing the programs 930. The computer 900 may include hardware, such an FPGA, an ASIC, etc. for executing the above-described various functions.

The computer 900 is, for example, a stationary computer or a portable computer, and is an electronic device in arbitrary form. The computer 900 may be a client computer, a server computer, or a cloud computer. The computer 900 may be applied to devices other than the devices 2 to 6.

### (Production History Information 30)

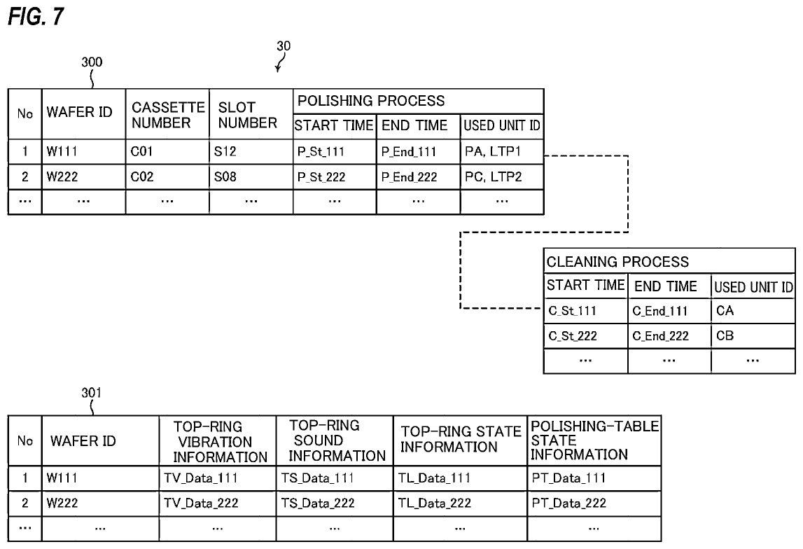

FIG. 7 is a data configuration diagram showing an example of the production history information 30 managed by the database device 3. The production history information 30 includes, for example, a wafer history table 300 with respect to each of the wafers W, and a polishing history table 301 with respect to the device-state information in the polishing process, as a table in which the reports R obtained in polishing of the wafers W for proper production are classified and registered. The production history information 30 includes a cleaning history table with respect to the device-state information in the cleaning process, an event history table with respect to the event information, a manipulation history table with respect to the manipulation information, and the like, in addition to the above-described tables, but detailed descriptions thereof are omitted.

For example, a wafer ID, a cassette number, a slot number, start time and end time of each process, a used unit ID, etc. are registered in each record of the wafer history table 300. The polishing process and the cleaning process are illustrated as examples in FIG. 7. Data is registered in the other processes in the same manner.

For example, a wafer ID, top-ring vibration information, top-ring sound information, top-ring state information, polishing-table state information, etc., are registered in each record of the polishing history table 301.

The top-ring vibration information is information indicating a state of vibration of the top ring 221 during the polishing process. The top-ring vibration information may include, for example, detection values of each sensor sampled at predetermined time intervals by the vibration sensor group, such as the acceleration sensor, the speed sensor, or the displacement sensor included in the top ring 221.

The top-ring sound information is information indicating a state of sound of the top ring 221 during the polishing process. The top-ring sound information may include, for example, detection values of each sensor sampled at predetermined time intervals by the sound sensor group, such as the directional sound collecting microphone that obtains the operating sound of the top ring included in the top ring 221, or the directional sound collecting microphone that obtains the processing sound of the polishing surface by the top ring.

The top-ring state information is information indicating a state of the top ring 221 in the polishing process. The top-ring state information may include, for example, detection values of each sensor sampled at predetermined time intervals by the sensor group of the top ring 221.

The polishing-table state information is information indicating a state of the polishing table 220 in the polishing process. The polishing-table state information may include, for example, detection values of each sensor sampled at predetermined time intervals by the sensor group of the polishing table 220.

By referring to the polishing history table 301, time-series data of each sensor can be extracted as a state of the substrate processing device 2 when the polishing process is performed on the wafer W identified by the wafer ID.

### (Polishing-Test Information 31)

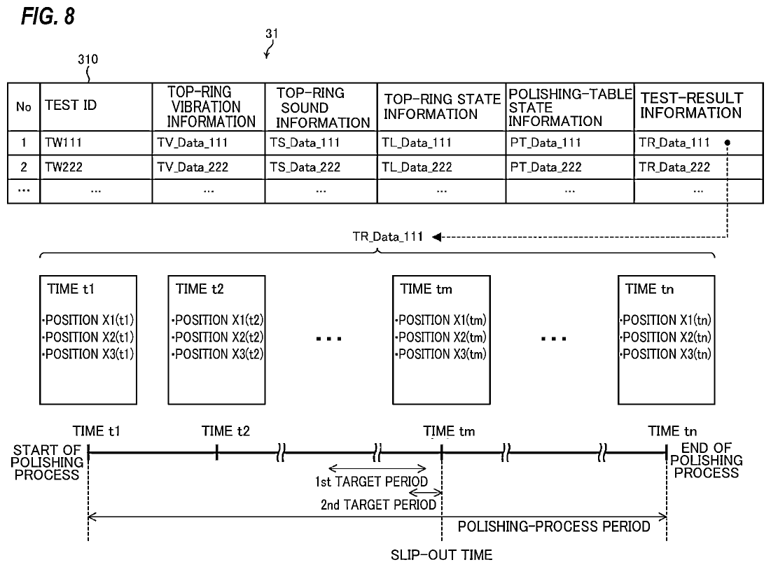

FIG. 8 is a data configuration diagram showing an example of the polishing-test information 31 managed by the database device 3. The polishing-test information 31 includes a polishing-test table 310 in which the reports R and the test results obtained in the polishing test performed using the dummy wafers are classified and registered.

For example, a test ID, the top-ring vibration information, the top-ring sound information, the top-ring state information, the polishing-table state information, test-result information, etc., are registered in each record of the polishing-test table 310. The top-ring vibration information, the top-ring sound information, the top-ring state information, and the polishing-table state information of the polishing-test table 310 are information indicating states of the respective sections in the polishing test. Data configurations of these information are the same as those of the polishing history table 301, and detailed descriptions will be omitted.

The test-result information is information indicating a state of the dummy wafer when the polishing process is performed on the dummy wafer in the polishing test using the test device. The test-result information is detection values of the dummy-wafer sensor of the dummy wafer sampled at predetermined time intervals by the dummy-wafer sensor. The test-result information in FIG. 8 shows a case of having three position sensors as the dummy-wafer sensors, and includes detection values X1 to X3 at time t1, t2, . . . , . . . tm, . . . , tn within a polishing-process period from start to end of the polishing process.

The test-result information may be the detection values of the dummy-wafer sensors as described above. Alternatively, a camera mounted to an optical microscope or a scanning electron microscope (SEM) may generate images of the dummy wafer at predetermined time intervals, and the test-result information may be obtained based on a result of image processing performed on the images, or based on a result of experimental analysis performed on the images by an experimenter.

The test-result information may be image data of an entire surface of the wafer generated by a camera installed at a predetermined position or in the device (for example, in the drying chamber 241), or may be scattering data of reflected wavelengths obtained by irradiating a front surface of the wafer with various wavelengths. The test-result information may be surface-state information obtained by an atomic force microscope (AFM).

Furthermore, the test-result information may be measurement data obtained by ellipsometry and reflectometry, measurement data obtained by phase interference method (interferometry), or measurement data obtained by sheet resistance and sonar scan.

The test-result information may be collected in one polishing test which is performed consecutively from start to end of the polishing process, or may be collected in multiple polishing tests which are performed repeatedly from start of the polishing process until the slip out occurs.

By referring to the polishing-test table 310, time-series data of each sensor indicating a state of the polishing unit 22 when the polishing process is performed on the dummy wafer in the polishing test identified by the test ID, and time-series data of the dummy-wafer sensor indicating positional shift of the dummy wafer at that time can be extracted. For example, data in a first target period before a slip-out time may be used to predict the occurrence of the slip out, and data in a second target period including the slip-out time may be used to determine whether the slip out has occurred.

### (Machine-Learning Device 4)

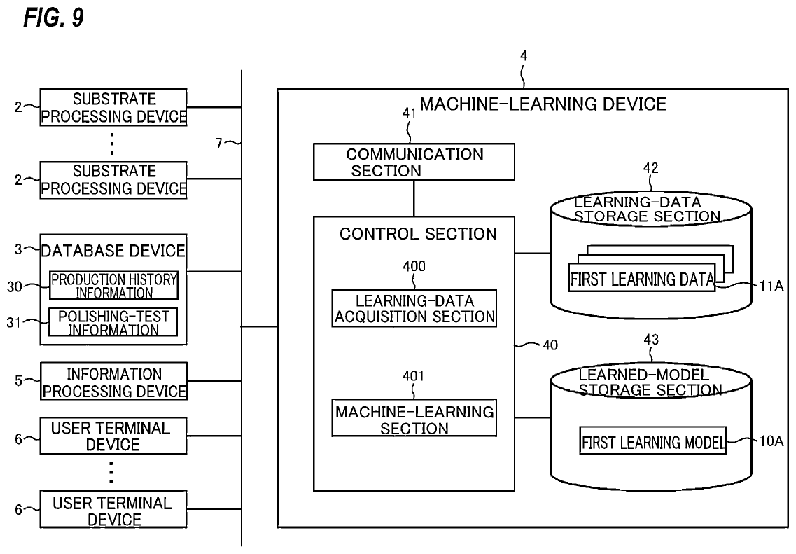

FIG. 9 is a block diagram showing an example of the machine-learning device 4 according to the first embodiment. The machine-learning device 4 includes a control section 40, a communication section 41, a learning-data storage section 42, and a learned-model storage section 43.

The control section 40 functions as a learning-data acquisition section 400 and a machine-learning section 401. The communication section 41 is coupled to external devices (e.g., the substrate processing device 2, the database device 3, the information processing device 5, the user terminal device 6, the polishing-test device (not shown), etc.) via the network 7. The communication section 41 serves as a communication interface configured to transmit and receive various data.

The learning-data acquisition section 400 is coupled to an external device via the communication section 41 and the network 7. The learning-data acquisition section 400 acquires the first learning data 11A including the polishing condition information as input data and slip-out predictive information as output data. The first learning data 11A is data used as teacher data (or training data), verification data, and test data in supervised learning. The slip-out predictive information is used as ground-truth label or correct label in the supervised learning.

The learning-data storage section 42 is a database that stores multiple sets of first learning data 11A acquired by the learning-data acquisition section 400. The specific configuration of the database that constitutes the learning-data storage section 42 may be designed as appropriate.

The machine-learning section 401 performs the machine learning using the multiple sets of first learning data 11A stored in the learning-data storage section 42. Specifically, the machine-learning section 401 inputs the multiple sets of first learning data 11A to the first learning model 10A and causes the first learning model 10A to learn a correlation between the polishing condition information and the slip-out predictive information included in the first learning data 11A to thereby create the first learning model 10A as a learned model.

The learned-model storage section 43 is a database configured to store the first learning model 10A as the learned model (i.e., adjusted weight parameter group) created by the machine-learning section 401. The first learning model 10A as the learned model stored in the learned-model storage section 43 is provided to a real system (e.g., the information processing device 5) via the network 7, a storage medium, or the like. Although the learning-data storage section 42 and the learned-model storage section 43 are shown as separate storage sections in FIG. 9, they may be configured as a single storage section.

The number of first learning model 10A stored in the learned-model storage section 43 is not limited to one. For example, a plurality of learning models may be stored in the learned-model storage section 43 for different conditions, such as for a difference in a machine learning method, mechanism and material of the top ring 221, a type of the membrane 2212, a type of the retainer ring 2213, a type of the polishing pad 2200, a type of the polishing fluid, a type of data included in the polishing condition information, a type of data included in the slip-out predictive information. In that case, a plurality of types of learning data having data configurations corresponding respectively to the plurality of learning models for the different conditions may be stored in the learning-data storage section 42.

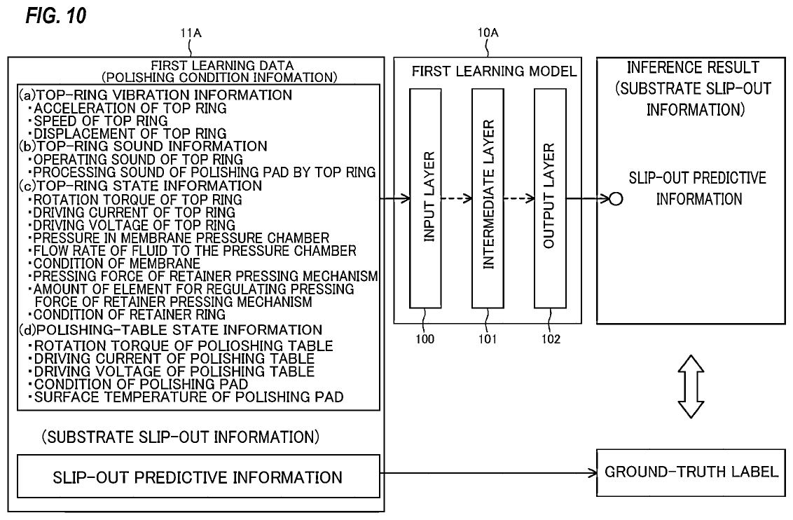

FIG. 10 is a diagram showing an example of the first learning model 10A and the first learning data 11A. The first learning data 11A used for the machine learning for the first learning model 10A includes the polishing condition information and the slip-out predictive information

The polishing condition information constituting the first learning data 11A include the top-ring vibration information indicating the vibration of the top ring 221 in the polishing process performed on the wafer W by the substrate processing device 2, the top-ring sound information indicating the sound generated by the top ring 221, the top-ring state information indicating the state of the top ring 221, and the polishing-table state information indicating the state of the polishing table 220.

The top-ring vibration information included in the polishing condition information is information indicating the vibration of the top ring 221 during the polishing process. The top-ring vibration information includes, for example, at least one of the acceleration of the top ring 221, the speed of the top ring 221, and the displacement of the top ring 221.

The top-ring sound information included in the polishing condition information is information indicating the sound of the top ring 221 during the polishing process. The top-ring sound information includes, for example, at least one of the operating sound of the top ring 221 and the processing sound of the polishing surface generated by the top ring.

The top-ring state information included in the polishing condition information includes at least one of the rotation torque of the top ring 221, the driving current of the top ring 221, the driving voltage of the top ring 221, the pressures (membrane pressures) in the membrane pressure chambers 2212a to 2212d, the flow rates (membrane flow-rates) of the pressurized fluid supplied to the membrane pressure chambers 2212a to 2212d, a condition of the membrane 2212, the pressure (retainer-ring airbag pressure) in the retainer-ring pressure chamber 2214a, the flow rate (retainer-ring airbag flow-rate) of the pressurized fluid supplied to the retainer-ring pressure chamber 2214a, and a condition of the retainer ring 2213. The condition of the membrane 2212 is represented by, for example, a surface property, an expansion and contraction state, a thickness, etc., and is set based on a use state of the membrane 2212 (e.g., use time, replaced or not replaced), the top-ring state information, the polishing-table state information, etc. The condition of the retainer ring 2213 is represented by, for example, a surface property, a flatness, a thickness, a cross-sectional shape, scraping or contamination of an inner periphery, and is set based on a use state of the retainer ring 2213 (e.g., use time, replaced or not replaced), the top-ring state information, the polishing-table state information, etc. For example, the conditions of the membrane 2212 and the retainer ring 2213 may change over time during the polishing process.

In this embodiment, since the retainer-ring airbag 2214 is used as the retainer-ring pressing mechanism, the top-ring state information included in the polishing condition information includes the pressure in the retainer-ring pressure chamber 2214a (retainer-ring airbag pressure), and the flow rate of pressurized fluid (retainer-ring airbag flow rate) supplied to the retainer-ring pressure chamber 2214a.

When another pressing mechanism is used as the retainer-ring pressing mechanism, the top-ring state information included in the polishing condition information may include a pressing force of the retainer-ring pressing mechanism or an amount of element that regulates the pressing force of the retainer-ring pressing mechanism. For example, when an electric actuator is used as the retainer-ring pressing mechanism, the top-ring state information included in the polishing condition information may include a pressing force of the electric actuator and an amount of current for adjusting the pressing force of the electric actuator. When an elastic member, such as a spring or a bag, is used as the retainer-ring pressing mechanism, the top-ring state information included in the polishing condition information may include a pressing force of the elastic member and a vertical position for adjusting the pressing force of the elastic member.

The polishing-table state information included in the polishing condition information includes at least one of the rotation torque of the polishing table 220, the driving current of the polishing table 220, the driving voltage of the polishing table 220, a condition of the polishing pad 2200, and the surface temperature of the polishing pad 2200. The condition of the polishing pad 2200 is represented by, for example, a surface property, a flatness, a cleanliness, a wetness, etc., and is set based on a use state of the polishing pad 2200 (e.g., use time, dressed or not dressed, replaced or not replaced, an image of the surface of the polishing pad 2200), the top-ring state information, the polishing-table state information, etc. For example, the condition of the polishing pad 2200 may change over time during the polishing process.

The substrate slip-out information constituting the first learning data 11A is information indicating the slip-out state of the wafer W that is polished under the state represented by the polishing condition information. In this embodiment, the substrate slip-out information is slip-out predictive information indicating a sign of the slip out in which the wafer W slips out from the top ring 221.

The learning-data acquisition section 400 acquires the first learning data 11A by referring to the polishing-test information 31 and receiving, as necessary, the input manipulations of the user through the user terminal device 6. For example, the learning-data acquisition section 400 refers to the polishing-test table 310 of the polishing-test information 31, thereby acquiring, as the polishing condition information, the top-ring vibration information, the top-ring sound information, the top-ring state information, and the polishing-table state information (time-series data of sensors of the top ring 221 and the polishing table 220) when the polishing test identified by the test ID is performed.

In this embodiment, a case will be described where the polishing condition information is acquired as the time-series data of the sensor group as shown in FIG. 10. The polishing condition information may be changed as appropriate according to constructions of the polishing unit 22 (particularly the top ring 21 and the polishing table 220). In addition, a command value to the module, a parameter converted from a detected value of the sensor or the command value to the module, or a parameter calculated based on detected values of a plurality of sensors may be used as the polishing condition information. Furthermore, the polishing condition information may be acquired as time-series data in the entire polishing-process period, may be acquired as time-series data in the target period that is part of the polishing-process period, or may be acquired as point-in-time data at a specific target point-in-time which may be the slip-out time. When the definition of the polishing condition information is changed as described above, the data structure of the input data in the first learning model 10A and the first learning data 11A may be changed as appropriate.

The learning-data acquisition section 400 refers to the polishing-test table 310 of the polishing-test information 31, thereby acquiring, as the slip-out predictive information corresponding to the polishing condition information, the test-result information when the polishing test identified by the same test ID is performed.

In this embodiment, a case will be described in which the substrate slip-out information is the slip-out predictive information as shown in FIG. 10.

The first learning model 10A employs, for example, a neural network structure, and includes an input layer 100, an intermediate layer 101, and an output layer 102. Synapses (not shown) connecting neurons are placed between the layers, and each synapse is associated with a weight. A weight parameter group including weights of the synapses is adjusted by the machine learning.

The input layer 100 has neurons corresponding to the polishing condition information as the input data, and each value of the polishing condition information is input to each neuron. The output layer 102 has neuron(s) corresponding to the slip-out predictive information as the output data, and a prediction result (inference result) of the slip-out predictive information for the polishing condition information is output as the output data.

When the first learning model 10A is constituted of a regression model, the slip-out predictive information is output as a numerical value normalized to a predetermined range (e.g., 0 to 1). When the first learning model 10A is constituted of a classification model, the slip-out predictive information is output as a numerical value normalized to a predetermined range (e.g., 0 to 1) as a score (confidence) for each class.

The inference results are set in advance to correspond to numerical values in the “predetermined range (0 to 1)”. For example, in the case of slip-out predictive information, the “predetermined range (0 to 1)” corresponding to the inference results may be divided into multiple ranges, which are associated with predictive times until the slip out will occur. In addition, in a case of slip-out occurrence information, a predetermined threshold value is set within the “predetermined range (0 to 1)” corresponding to the inference results. If an output numerical value is below the threshold value, “no occurrence” is determined. If an output numerical value exceeds the threshold value, “occurrence” is determined. The sign (prediction) of the slip out, or occurrence or no occurrence of the slip out is output according to the inference result.

### (Machine-Learning Method)

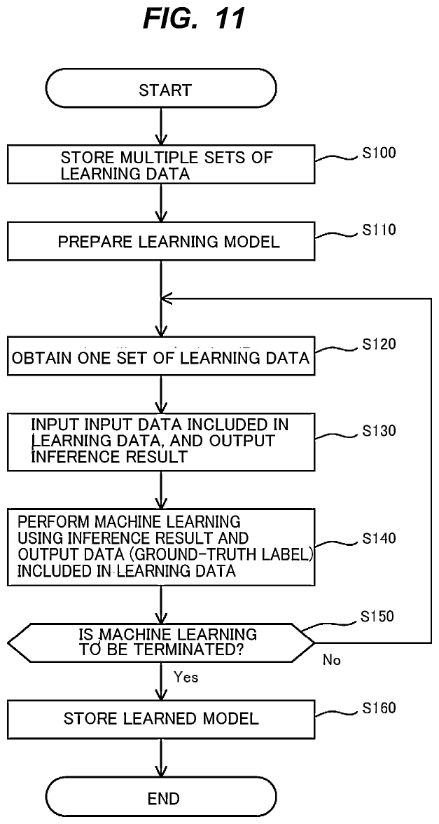

FIG. 11 is a flowchart illustrating an example of a machine-learning method performed by the machine-learning device 4.

First, in step S100, the learning-data acquisition section 400 obtains, from the polishing-test information 31 or the like, a desired number of first learning data 11A as advance preparation for starting the machine learning, and stores the obtained first learning data 11A in the learning-data storage section 42. The number of first learning data 11A to be prepared may be set in consideration of the inference accuracy required for the first learning model 10A finally obtained.

Next, in step S110, the machine-learning section 401 prepares the first learning model 10A before learning for starting the machine learning. The first learning model 10A prepared before learning in this embodiment is composed of the neural network model illustrated in FIG. 10, and the weight of each synapse is set to an initial value.

Next, in step S120, the machine-learning section 401 randomly obtains, for example, one set of first learning data 11A from the multiple sets of first learning data 11A stored in the learning-data storage section 42.

Next, in step S130, the machine-learning section 401 inputs the polishing condition information (input data) included in the one set of first learning data 11A to the input layer 100 of the prepared first learning model 10A before learning (or during learning). As a result, the slip-out predictive information (the output data) is output as the inference result from the output layer 102 of the first learning model 10A. However, the output data is generated by the first learning model 10A before learning (or during learning). Therefore, in the state before learning (or during learning), the output data output as the inference result may indicate different information from the slip-out predictive information (ground-truth label) included in the first learning data 11A.

Next, in step S140, the machine-learning section 401 performs the machine learning by comparing the slip-out predictive information (ground-truth label) included in the one set of first learning data 11A acquired in the step S120 with the slip-out predictive information (output data) output as the inference result from the output layer in the step S130, and adjusting the weight of each synapse (backpropagation). In this way, the machine-learning section 401 causes the first learning model 10A to learn a correlation between the polishing condition information and the slip-out predictive information.

Next, in step S150, the machine-learning section 401 determines whether a predetermined learning end condition is satisfied. For example, this determination is made based on an evaluation value of an error function based on the slip-out predictive information (ground-truth label) included in the first learning data 11A and the slip-out predictive information (output data) output as the inference result, or the remaining number of unlearned first learning data 11A stored in the learning-data storage section 42.

In the step S150, if the machine-learning section 401 has determined that the learning end condition is not satisfied and the machine learning is to be continued (“No” in the step S150), the process returns to the step S120, and the steps S120 to S140 are performed on the first learning model 10A multiple times using the unlearned first learning data 11A. On the other hand, if the machine-learning section 401 has determined that the learning end condition is satisfied and the machine learning is to be terminated (“Yes” in the step S150) in the step S150, the process proceeds to step S160.

Then, in the step S160, the machine-learning section 401 stores, in the learned-model storage section 43, the first learning model 10A as the learned model (adjusted weight parameter group) created by adjusting the weight associated with each synapse. The sequence of machine-learning processes shown in FIG. 11 is completed. In the machine-learning method, the step S100 corresponds to a learning-data storing process, the steps S110 to S150 correspond to a machine-learning process, and the step S160 corresponds to a learned-model storing process.

As described above, the machine-learning device 4 and the machine-learning method according to the present embodiment can provide the first learning model 10A capable of predicting (inferring) the slip-out predictive information indicating the state of the wafer W from the polishing condition information including the top-ring vibration information, the top-ring sound information, the top-ring state information, and the polishing-table state information.

### (Information Processing Device 5)

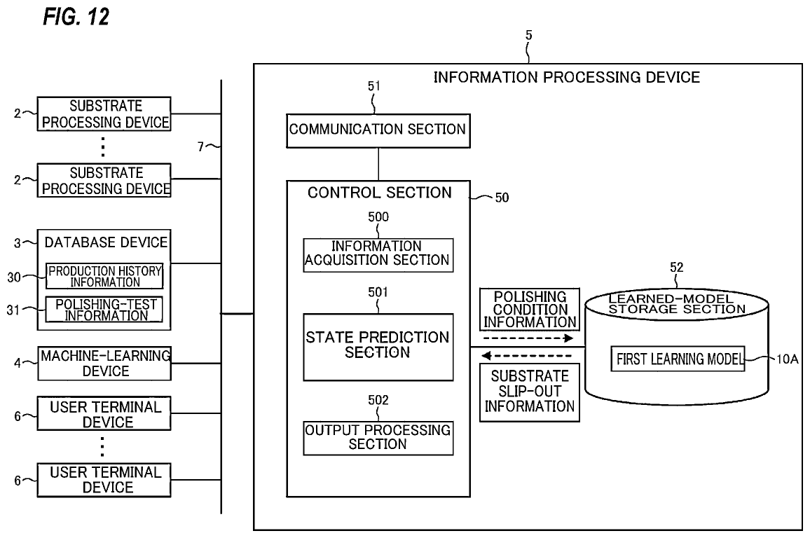

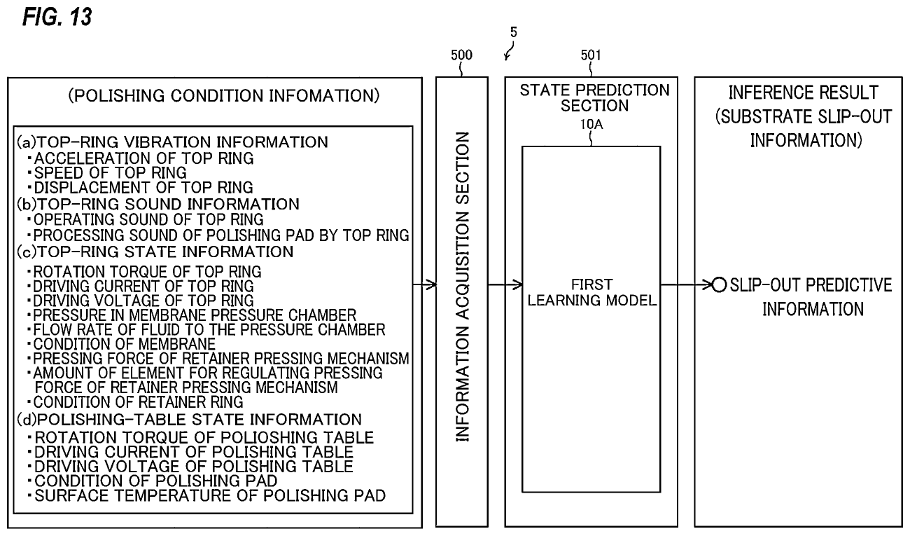

FIG. 12 is a block diagram showing an example of the information processing device 5 according to the first embodiment. FIG. 13 is a functional explanatory diagram showing an example of the information processing device 5 according to the first embodiment. The information processing device 5 includes a control section 50, a communication section 51, and a learned-model storage section 52.

The control section 50 functions as an information acquisition section 500, a state prediction section 501, and an output processing section 502. The communication section 51 is coupled to the external devices (e.g., the substrate processing device 2, the database device 3, the machine-learning device 4, the user terminal device 6, etc.) via the network 7, and serves as a communication interface configured to transmit and receive various data.

The information acquisition section 500 is coupled to an external device via the communication section 51 and the network 7, and acquires the polishing condition information including the top-ring vibration information, the top-ring sound information, the top-ring state information, and the polishing-table state information.

For example, when the “real-time-predicting process” of the substrate slip-out information is performed for the wafer W during polishing, the information acquisition section 500 receives the report R on the device-state information from the substrate processing device 2 performing the polishing of the wafer W, thereby acquiring the polishing condition information including the top-ring vibration information, the top-ring sound information, the top-ring state information, and the polishing-table state information during the polishing process of the wafer W.

As described above, the state prediction section 501 inputs the polishing condition information acquired by the information acquisition section 500 as the input data to the first learning model 10A, thereby predicting the substrate slip-out information (in this embodiment, the slip-out predictive information) for the wafer W on which the polishing process indicated by the polishing condition information is performed.

The learned-model storage section 52 is a database configured to store the first learning model 10A as the learned model for use in the state prediction section 501. The number of first learning model 10A stored in the learned-model storage section 52 is not limited to one. For example, a plurality of learned models 10A may be stored in the learned-model storage section 52 for different states, such as for a difference in a machine learning method, mechanism and material of the top ring 221, a type of the membrane 2212, a type of the retainer ring 2213, a type of the polishing pad 2200, a type of the polishing fluid, a type of data included in the polishing condition information, and a type of data included in the slip-out predictive information. The plurality of learned models 10A may be selectively used. The learned-model storage section 52 may be a storage section of an external computer (e.g., a server type computer or a cloud type computer). In that case, the state prediction section 501 accesses the external computer.

The output processing section 502 performs output processing to output the slip-out predictive information generated by the state prediction section 501. For example, the output processing section 502 may transmit the slip-out predictive information to the user terminal device 6, so that a display screen based on the slip-out predictive information may be displayed on the user terminal device 6. The output processing section 502 may transmit the slip-out predictive information to the database device 3, so that the slip-out predictive information may be registered in the production history information 30.

### (Information Processing Method)

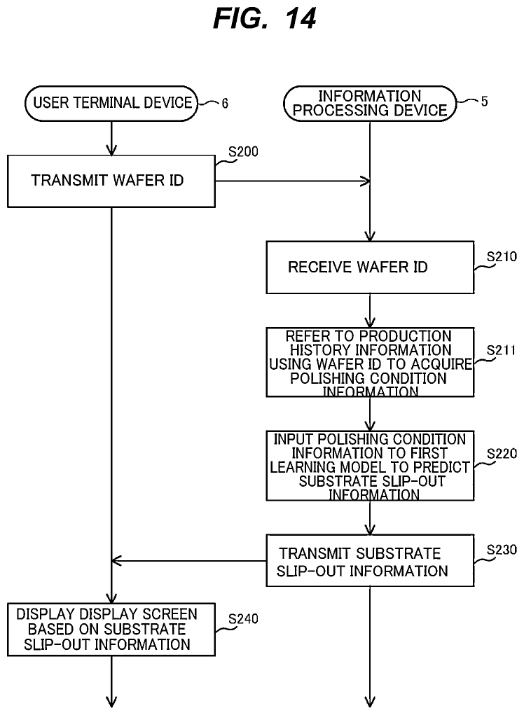

FIG. 14 is a flowchart illustrating an example of an information processing method performed by the information processing device 5. In this embodiment, an operation example will be described in a case where the user manipulates the user terminal device 6 to perform the “predicting process” of the substrate slip-out information for a specific wafer W.

First, in step S200, when the user performs an input operation of inputting a wafer ID for identifying a wafer W to be predicted on the user terminal device 6, the user terminal device 6 transmits the wafer ID to the information processing device 5.

Next, in step S210, the information acquisition section 500 of the information processing device 5 receives the wafer ID transmitted in the step S200. In step S211, the information acquisition section 500 uses the wafer ID received in the step S210 to refer to the polishing history table 301 of the production history information 30, thereby acquiring the polishing condition information when the polishing process is performed on the wafer W identified by the wafer ID.

Next, in step S220, the state prediction section 501 inputs the polishing condition information acquired in the step S211 as input data to the first learning model 10A, thereby generating, as output data, the slip-out predictive information for the polishing condition information and predicts a state of the wafer W.

Next, in step S230, the output processing section 502 transmits the slip-out predictive information to the user terminal device 6 as an output process for outputting the slip-out predictive information generated in the step S220. The slip-out predictive information may be transmitted to the database device 3 in addition to or instead of the user terminal device 6.

Next, in step S240, upon receiving the slip-out predictive information transmitted in the step S230, the user terminal device 6 displays a display screen based on the slip-out predictive information as a response to the transmission process in the step S200. As a result, the state of the wafer W can be visually recognized by the user. In the above information processing method, the steps S210 and S211 correspond to an information acquisition process, the step S220 corresponds to a state prediction process, and the step S230 corresponds to an output processing process.

As described above, the information processing device 5 and the information processing method according to the present embodiment inputs the polishing condition information including the top-ring vibration information, the top-ring sound information, the top-ring state information, and the polishing-table state information in the polishing process to the first learning model 10A, so that the substrate slip-out information (slip-out predictive information) for the polishing condition information can be predicted. Therefore, the state of the wafer W during or after polishing can be predicted appropriately.

### Second Embodiment

A second embodiment differs from the first embodiment in that “post-prediction process” is performed for the slip-out occurrence information as the substrate slip-out information for the wafer W after the polishing process has already been performed. In this embodiment, a machine-learning device 4a and an information processing device 5a according to the second embodiment will be described, focusing on differences from the first embodiment.

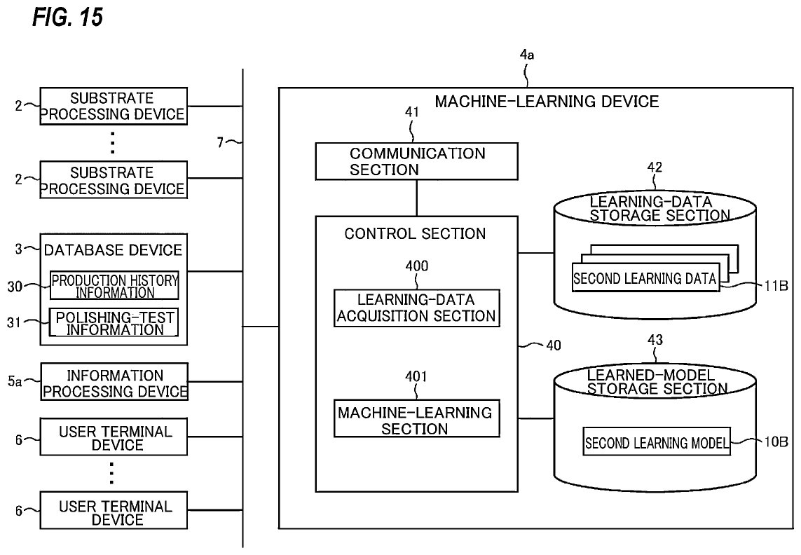

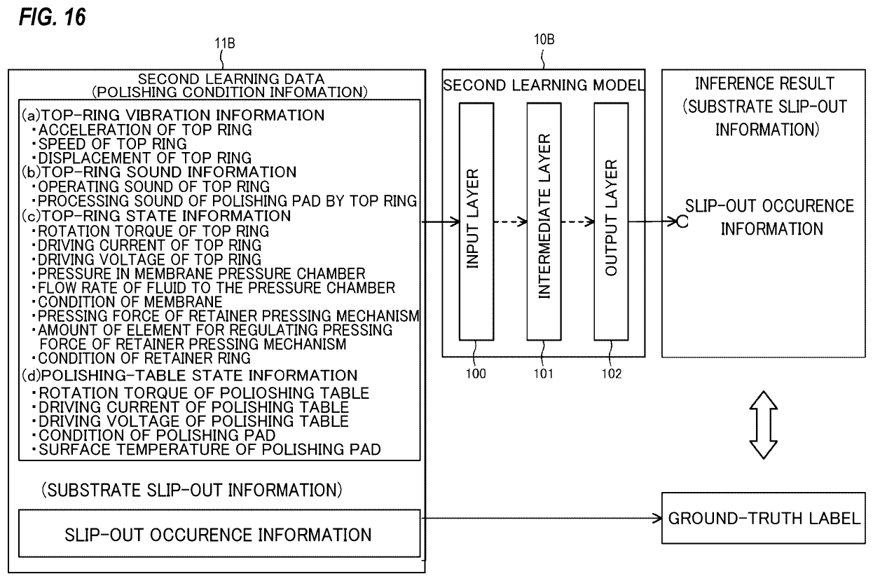

FIG. 15 is a block diagram showing an example of the machine-learning device 4a according to the second embodiment. FIG. 16 is a diagram showing an example of a second learning model 10B and second learning data 11B. The second learning data 11B is used for machine learning for the second learning model 10B.

The substrate slip-out information constituting the second learning data 11B is the slip-out occurrence information indicating whether or not the slip out of the wafer W from the top ring 221 has occurred. The polishing condition information constituting the second learning data 11B is the same as that in the first embodiment, and therefore descriptions thereof will be omitted.

The learning-data acquisition section 400 acquires the second learning data 11B by referring to the polishing-test information 31 and receiving, as necessary, the input manipulations of the user through the user terminal device 6. For example, by referring to the polishing test table 310 of the polishing test information 31, the learning-data acquisition section 400 can obtain the polishing condition information including the top-ring vibration information, the top-ring sound information, the top-ring state information, and the polishing-table state information (time-series data of each sensor included in each of the top ring 221 and the polishing table 220).

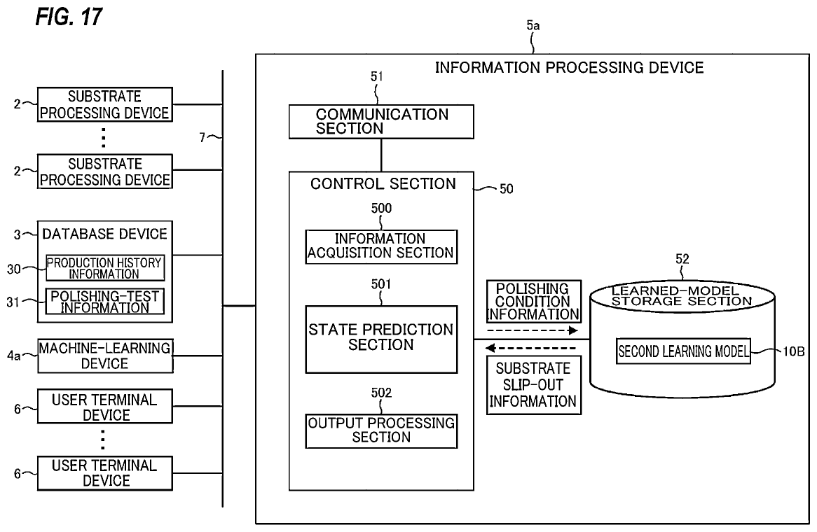

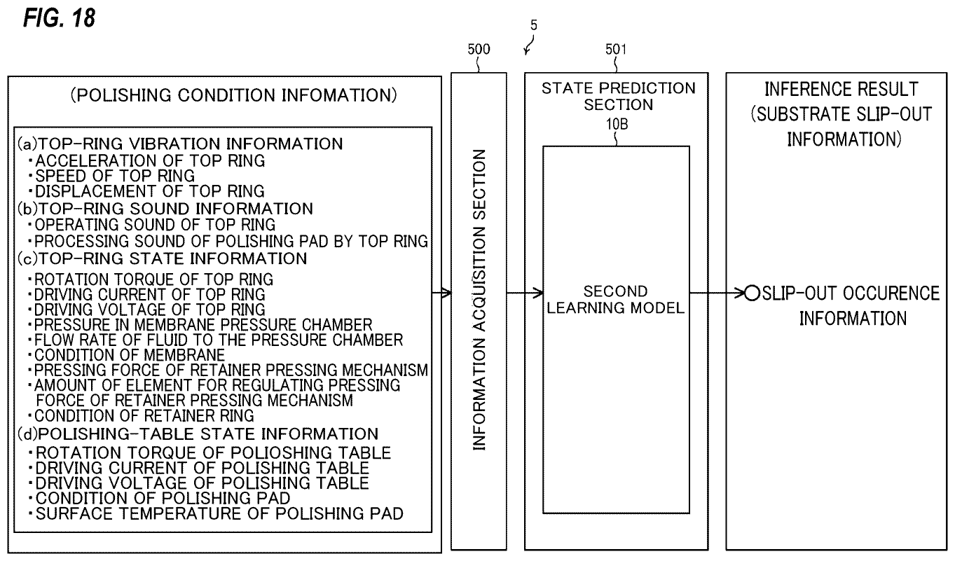

FIG. 17 is a block diagram showing an example of an information processing device 5a functioning as the information processing device 5a according to the second embodiment. FIG. 18 is a functional explanatory diagram showing an example of the information processing device 5a according to the second embodiment.

Similar to the first embodiment, the information acquisition section 500 acquires the polishing condition information including the top-ring vibration information, the top-ring sound information, the top-ring state information, and the polishing-table state information.

When “post-prediction process” of the substrate slip-out information for a wafer W is performed after the polishing process of the wafer W has already been performed, the information acquisition section 500 may refer to the polishing history table 301 of the production history information 30 to acquire the polishing condition information including the top-ring vibration information, the top-ring sound information, the top-ring state information, and the polishing-table state information which have been used in the polishing process of the wafer W.

As described above, the state prediction section 501 inputs the polishing condition information acquired by the information acquisition section 500 as the input data to the second learning model 10B, thereby predicting the substrate slip-out information (in this embodiment, the slip-out occurrence information) for the wafer W on which the polishing process is performed under conditions indicated by the polishing condition information.

As described above, the information processing device 5a and the information processing method according to the present embodiment input the polishing condition information including the top-ring vibration information, the top-ring sound information, the top-ring state information, and the polishing-table state information in the polishing process to the second learning model 10B, so that the substrate slip-out information (the slip-out occurrence information) corresponding to the polishing condition information can be predicted. Therefore, the occurrence of the slip out of the wafer W in the polishing process can be predicted appropriately.

### OTHER EMBODIMENTS

The present invention is not limited to the above-described embodiments, and various modifications can be made and used without deviating from the scope of the present invention. All of them are included in the technical concept of the present invention.

In the above-described embodiments, the database device 3, the machine-learning device 4, and the information processing device 5 are described as being configured as separate devices, but these three devices may be configured as a single device. In one embodiment, any two of these three devices may be configured as a single device. Further, at least one of the machine-learning device 4, and the information processing device 5 may be incorporated into the control unit 26 of the substrate processing device 2 or the user terminal device 6.

In the above-described embodiments, the substrate processing device 2 is described as including the units 21 to 25, but the substrate processing device 2 may include at least the polishing unit 22, and the other units may be omitted.

In the embodiments described above, the neural network is employed as the learning model that implements the machine learning performed by the machine-learning section 401, while any other machine-learning model may be employed. Examples of the other machine-learning model include tree type (e.g., decision tree, regression tree), ensemble learning (e.g., bagging, boosting), neural network type including deep learning (e.g., recurrent neural network, convolutional neural network, LSTM), clustering type (e.g., hierarchical clustering, non-hierarchical clustering, k-nearest neighbor algorithm, k-means clustering), multivariate analysis (e.g., principal component analysis, factor analysis, logistic regression), and support vector machine.

In the above embodiments, the test-result information is information indicating the state when the polishing process is performed in the polishing test using a dummy wafer in the test device. In one embodiment, a position sensor may be installed as a slip-out sensor to detect the slip-out. The test-result information may be continuously acquired as information indicating a state when an actual polishing process of a wafer is performed using the actual polishing unit 22 provided with the position sensor. The continuously acquired test-result information is continuously learned by the machine learning device 4.

The test-result information may be continuously acquired in the polishing unit 22, which does not have a position sensor serving as a slip-out sensor. Specifically, a human may determine the sign or occurrence of the slip-out and may label the data.

Furthermore, the information continuously acquired using the actual polishing unit 22 may be uploaded to a cloud. After the machine learning is performed in the cloud, the learned model may be deployed to the substrate processing device 2. In one embodiment, the substrate processing device 2 may learn the processing method therein without uploading the data to the cloud.

### (Machine Learning Program and Information Processing Program)

The present invention can be provided in a form of a program (machine learning program) that causes the computer 900 to function as each section of the machine-learning device 4, and in a form of a program (machine learning program) that causes the computer 900 to execute each process of the machine-learning method. Further, the present invention can be provided in a form of a program (information processing program) that causes the computer 900 to function as each section included in the information processing device 5, and in a form of a program (information processing program) that causes the computer 900 to execute each process of the information processing method according to the above-described embodiments.

### (Inference Apparatus, Inference Method, and Inference Program)

The present invention can be provided not only in a form of the information processing device 5 (information processing method or information processing program) according to the above-described embodiments, but also in a form of an inference apparatus (inference method or inference program) used for inferring the substrate slip-out information. In that case, the inference apparatus (inference method or inference program) may include a memory and a processor. The processor may execute a series of processes. The series of processes includes an information acquisition processing (information acquisition process) of acquiring the polishing condition information, and an inference processing (inference process) of inferring the substrate slip-out information (stress information or polishing quality information) indicating the state of the substrate that is polished under the conditions indicated by the polishing condition information that is acquired in the information acquisition processing. The series of processing further includes an information acquisition processing (information acquisition process) of acquiring the stress information, and an inference processing (inference process) of inferring the polishing quality information indicating the polishing quality of the substrate to which the stress indicated by the stress information is applied when acquiring the stress information in the information acquisition processing.

The form of the inference apparatus (inference method or inference program) can be applied to various devices more easily than when the information processing device is implemented. It is readily understood by a person skilled in the art that the state prediction section may be applied with use of the learning model as the learned model created by the machine-learning device and the machine-learning method according to the above-described embodiments when the inference apparatus (inference method or inference program) infers the substrate slip-out information.

### INDUSTRIAL APPLICABILITY

The present invention is applicable to an information processing apparatus, an inference apparatus, a machine-learning device, an information processing method, an inference method, and a machine-learning method.

### REFERENCE SIGNS LIST

1 . . . substrate processing system, 2 . . . substrate processing device, 3 . . . database device, 4, 4a . . . machine-learning device, 5, 5a . . . information processing device,
6 . . . user terminal device, 7 . . . network,
10 . . . learning model, 10A . . . first learning model, 10B . . . second learning model,
11A . . . first learning data, 11B . . . second learning data,
20 . . . housing, 21 . . . load-unload unit,
22 . . . polishing unit, 22A˜22D . . . polishing section, 23 . . . substrate transport unit,
24 . . . cleaning unit, 25 . . . film-thickness measuring unit, 26 . . . control unit,
30 . . . production history information, 31 . . . polishing-test information,
40 . . . control section, 41 . . . communication section, 42 . . . learning-data storage section,
43 . . . learned-model storage section,
50 . . . control section, 51 . . . communication section, 52 . . . learned-model storage section,
220 . . . polishing table, 221 . . . top ring, 222 . . . polishing-fluid supply nozzle,
223 . . . dresser, 224 . . . atomizer, 225 . . . environment sensor
260 . . . control section, 21 . . . communication section, 262 . . . input section, 263 . . . output section,
264 . . . memory section,
300 . . . wafer history table, 301 . . . polishing history table, 310 . . . polishing-test table,
400 . . . learning-data acquisition section, 401 . . . machine-learning section,
500 . . . information acquisition section, 501 . . . state prediction section, 502 . . . output processing section,
900 . . . computer
2200 . . . polishing pad, 2210 . . . top ring body, 2211 . . . carrier,
2212 . . . membrane, 2212a-2212d . . . membrane pressure chamber,
2213 . . . retainer ring, 2214 . . . retainer-ring airbag (retainer-ring pressing mechanism),
2214a . . . retainer-ring pressure chamber

1. An information processing apparatus comprising:
an information acquisition section configured to acquire polishing condition information including top-ring vibration information indicating vibration of a top ring in chemical mechanical polishing of the substrate and top-ring sound information indicating sound generated from the top ring in the chemical mechanical polishing of the substrate, the chemical mechanical polishing being performed by a substrate processing apparatus including a polishing table rotatably supporting the polishing pad and the top ring configured to press the substrate against the polishing pad; and
a state prediction section configured to predict substrate slip-out information for the polishing condition information by inputting the polishing condition information acquired by the information acquisition section to a learning model that has been generated by machine learning that causes the learning model to learn a correlation between the polishing condition information and the substrate slip-out information indicating occurrence of slip out of the substrate on which the chemical mechanical polishing is performed.

2. The information processing apparatus according to claim 1, wherein the polishing condition information further includes top-ring state information indicating a state of the top ring in polishing of the substrate.

3. The information processing apparatus according to claim 1, wherein the polishing condition information further includes polishing-table state information indicating a state of the polishing table in polishing of the substrate.

4. The information processing apparatus according to claim 1, wherein the top-ring vibration information included in the polishing condition information includes at least one of:
acceleration of the top ring;
speed of the top ring; and
displacement of the top ring.

5. The information processing apparatus according to claim 1, wherein the top-ring sound information included in the polishing condition information includes at least one of:
operating sound of the top ring; and
processing sound of the polishing surface generated by the top ring.

6. The information processing apparatus according to claim 2, wherein the top ring includes:
a top ring body which is moved by a rotating mechanism, a vertical movement mechanism, and an oscillation mechanism;
a membrane housed in the top ring body and configured to press the substrate against the polishing pad according to pressurized fluid supplied to a membrane pressure chamber; and
a retainer ring disposed at a periphery of the membrane and configured to press the polishing pad according to pressurized fluid supplied to a retainer-ring pressure chamber, and
the top-ring state information included in the polishing condition information includes at least one of:
a rotation torque of the top ring;
a driving current of the top ring;
a driving voltage of the top ring;
a pressure in the membrane pressure chamber;
a flow rate of the pressurized fluid supplied to the membrane pressure chamber;
a condition of the membrane;
a pressing force of the retainer-ring pressing mechanism;
an amount of element for regulating a pressing force of the retainer-ring pressing mechanism; and
a condition of the retainer ring.

7. The information processing apparatus according to claim 3, wherein the polishing-table state information included in the polishing condition information includes at least one of:
a rotation torque of the polishing table;
a driving current of the polishing table;
a driving voltage of the polishing table;
a condition of the polishing pad; and
a surface temperature of the polishing pad.

8. The information processing apparatus according to claim 1, wherein the substrate slip-out information comprises slip-out predictive information indicating a sign of slip-out of the substrate that will occur before the slip-out of the substrate occurs.

9. The information processing apparatus according to claim 1, wherein the substrate slip-out information comprises slip-out occurrence information indicating whether slip-out of the substrate has occurred.

10. An inference apparatus comprising:
a memory; and
a processor,
the processor being configured to perform:
an information acquisition process of acquiring polishing condition information including top-ring vibration information indicating vibration of a top ring in chemical mechanical polishing of the substrate and top-ring sound information indicating sound generated from the top ring or a polishing table in the chemical mechanical polishing of the substrate performed by a substrate processing apparatus including the polishing table rotatably supporting the polishing pad and the top ring configured to press the substrate against the polishing pad; and
an inference process of inferring substrate slip-out information indicating occurrence of slip out of the substrate on which the chemical mechanical polishing is performed under conditions indicated by the polishing condition information when the polishing condition information is acquired in the information acquisition process.

11. A machine-learning apparatus comprising:
a learning-data storage section storing multiple sets of learning data including polishing condition information and substrate slip-out information, the polishing condition information including top-ring vibration information indicating vibration of a top ring in chemical mechanical polishing of the substrate and top-ring sound information indicating sound generated from the top ring in the chemical mechanical polishing of the substrate performed by a substrate processing apparatus including a polishing table rotatably supporting the polishing pad and the top ring configured to press the substrate against the polishing pad, the substrate slip-out information indicating occurrence of slip out of the substrate on which the chemical mechanical polishing is performed;
a machine-learning section configured to cause a learning model to learn a correlation between the polishing condition information and the substrate slip-out information by inputting the multiple sets of learning data to the learning model; and
a learned-model storage section configured to store the learning model that has learned the correlation by the machine-learning section.

12. An information processing method comprising:
an information acquisition process of acquiring polishing condition information including top-ring vibration information indicating vibration of a top ring in chemical mechanical polishing of the substrate and top-ring sound information indicating sound generated from the top ring in the chemical mechanical polishing of the substrate performed by a substrate processing apparatus including a polishing table rotatably supporting the polishing pad and the top ring configured to press the substrate against the polishing pad; and
a state prediction process of predicting substrate slip-out information for the polishing condition information by inputting the polishing condition information acquired by the information acquisition process to a learning model that has been generated by machine learning that causes the learning model to learn a correlation between the polishing condition information and the substrate slip-out information indicating occurrence of slip out of the substrate on which the chemical mechanical polishing is performed.

13. An inference method executed by an inference apparatus including a memory and a processor, the processor performing:
an information acquisition process of acquiring polishing condition information including top-ring vibration information indicating vibration of a top ring in chemical mechanical polishing of the substrate and top-ring sound information indicating sound generated from the top ring in the chemical mechanical polishing of the substrate performed by a substrate processing apparatus including a polishing table rotatably supporting the polishing pad and the top ring configured to press the substrate against the polishing pad; and
an inference process of inferring substrate slip-out information indicating occurrence of slip out of the substrate on which the chemical mechanical polishing is performed under conditions indicated by the polishing condition information when the polishing condition information is acquired in the information acquisition process.

14. A machine-learning method comprising:
a learning-data storage process of storing multiple sets of learning data including polishing condition information and substrate slip-out information, the polishing condition information including top-ring vibration information indicating vibration of a top ring in chemical mechanical polishing of the substrate and top-ring sound information indicating sound generated from the top ring in the chemical mechanical polishing of the substrate performed by a substrate processing apparatus including a polishing table rotatably supporting the polishing pad and the top ring configured to press the substrate against the polishing pad, the substrate slip-out information indicating occurrence of slip out of the substrate on which the chemical mechanical polishing is performed;
a machine-learning process of causing a learning model to learn a correlation between the polishing condition information and the substrate slip-out information by inputting the multiple sets of learning data to the learning model; and
a learned-model storage process of storing the learning model that has learned the correlation by the machine-learning section.
